(19) United States
(12) Patent Application Publication
(10) Pub. No.: US 2019/0280142 A1
(43) Pub. Date: Sep. 12, 2019

(54) SOLAR CELL, MULTI-JUNCTION SOLAR CELL, SOLAR CELL MODULE, AND SOLAR POWER GENERATION SYSTEM

(71) Applicant: Kabushiki Kaisha Toshiba, Minato-ku (JP)

(72) Inventors: Soichiro SHIBASAKI, Nerima (JP); Sara Yoshio, Yokohama (JP); Naoyuki Nakagawa, Setagaya (JP); Mutsuki Yamazaki, Yokohama (JP); Kazushige Yamamoto, Yokohama (JP); Yuya Honishi, Yokohama (JP)

(73) Assignee: Kabushiki Kaisha Toshiba, Minato-ku (JP)

(21) Appl. No.: 16/113,170

(22) Filed: Aug. 27, 2018

(30) Foreign Application Priority Data
Mar. 6, 2018 (JP) 2018-039780

(51) Int. Cl. H01L 31/061; H01L 31/0216; H01L 31/0725; H01L 31/0749; H01L 31/18; H02S 40/32; H02S 40/38

(52) U.S. Cl. CPC H01L 31/061; H01L 31/02168; H01L 31/0725; H02S 40/38; H01L 31/18; H02S 40/32; H01L 31/0749

(57) ABSTRACT

According to one embodiment, a solar cell includes a first electrode, a second electrode, a light-absorbing layer, and a plurality of metal parts. The light-absorbing layer is interposed between the first electrode and the second electrode. The metal parts are present on a surface of the first electrode opposing the second electrode. A void is provided in at least a part between the metal parts.

### CROSS-REFERENCE TO RELATED APPLICATION

This application is based upon and claims the benefit of priority from Japanese Patent Application No. 2018-039780, filed on Mar. 6, 2018; the entire contents of which are incorporated herein by reference.

### FIELD

Embodiments described herein relate generally to a solar cell, a multi-junction solar cell, a solar cell module, and a solar power generation system.

### BACKGROUND

As a high efficiency solar cell, there is a multi-junction (tandem) solar cell. Since this multi-junction solar cell can use high efficiency cells for each wavelength band, it is expected to have higher efficiency than a single-junction solar cell. A chalaopyrite solar cell including CIGS is known to have high efficiency, and can be a top cell candidate by making a wide gap. However, in the case that it is used as a top cell, it is necessary to use a first electrode for transmitting light having a band gap or less. When directly forming a light-absorbing layer on the first electrode, an interface is oxidized, so that good contact is not formed, and it is difficult to raise efficiency.

### BRIEF DESCRIPTION OF THE DRAWINGS

FIG. 1 is a conceptual sectional view of a solar cell according to a first embodiment.

FIG. 2 is an image diagram according to a first embodiment.

FIG. 3 is a cross-sectional view representing an outline of void fraction-measurement.

FIG. 4 is another cross-sectional view representing an outline of void fraction-measurement.

FIG. 5 is a conceptual sectional view of a solar cell according to a second embodiment.

FIG. 6 is a conceptual sectional view of a solar cell according to a third embodiment.

FIG. 7 is a sectional TEM image of a solar cell according to a third embodiment.

FIG. 8 is a conceptual sectional view of a solar cell according to a fourth embodiment.

FIG. 9 is a conceptual sectional view of a multi-junction solar cell according to a fifth embodiment.

FIG. 10 is a conceptual diagram of a solar cell module according to a sixth embodiment.

FIG. 11 is a conceptual diagram of a solar cell system according to a seventh embodiment.

### DETAILED DESCRIPTION

Hereinafter, preferred embodiments will be described in detail with reference to the accompanying drawings.

According to one embodiment, a solar cell includes a first electrode, a second electrode, a light-absorbing layer, and a plurality of metal parts. The light-absorbing layer is interposed between the first electrode and the second electrode. The metal parts are present on a surface of the first electrode opposing the second electrode. A void is provided in at least a part between the metal parts.

### First Embodiment

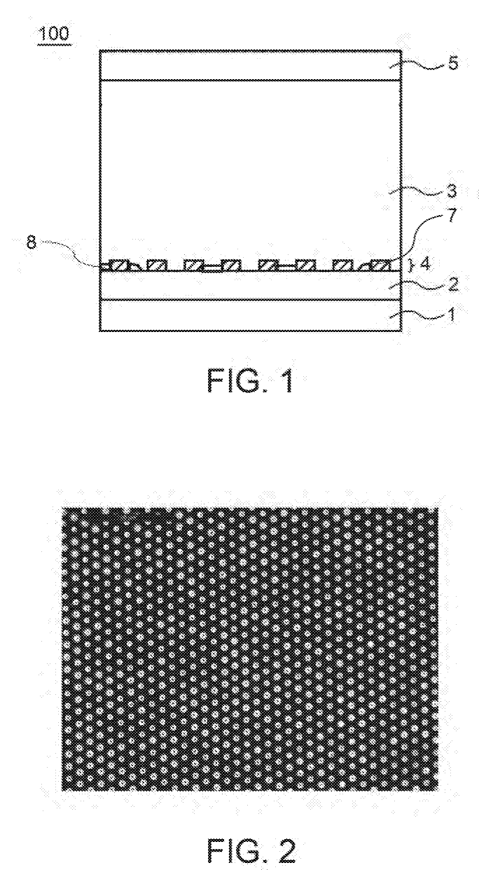

As shown in FIG. 1, a solar cell 100 according to the first embodiment includes a substrate 1, a first electrode 2 on the substrate 1, a second electrode 5 above the first electrode 2, and a light-absorbing layer 3 interposed between the first electrode 2 and the second electrode 5. Further, the solar cell has a dot region 4 between the first electrode 2 and the light-absorbing layer 3. In this dot region 4, there is a plurality of conductive metal parts 7. The light-absorbing layer 3 includes a void 8 in at least a part between the plurality of metal parts 7.

The void 8 is provided in at least a part between the metal parts 7, thereby increasing parallel resistance as a characteristic of the solar cell, and raising a shape factor, leading to efficiency improvement. In addition, since there is a large difference in refractive index between the light-absorbing layer 3 and the void 8, incident light is partially reflected on the void 8 to return to the inside of the light-absorbing layer 3. Therefore, absorption inside the light-absorbing layer 3 is increased, leading to efficiency improvement.

The members constituting the solar cell according to the present embodiment is described.

(Substrate)

It is preferred that the substrate 1 according to the first embodiment uses soda-lime glass, and general glass such as quartz, white board glass and chemically tempered glass, metal plates such as stainless, titanium (Ti) or chromium (Cr), or resins such as polyimide and acryls may be used.

(First Electrode)

The first electrode 2 according to the first embodiment is an electrode of the solar cell 100. The first electrode 2 is, for example, a transparent electrode including a semiconductor film formed on the substrate 1. The first substrate 2 is present between the substrate 1 and the light-absorbing layer 3. As the first electrode 2, a semiconductor film containing at least indium-tin oxide (ITO) may be used. On ITO of the light-absorbing layer 3 side, a layer containing oxides such as SnO₂, TiO₂, carrier-doped ZnO:Ga and ZnO:Al may be stacked. ITO and Sno₂ may be stacked from the substrate 1 side to the light-absorbing layer 3 side, or ITO, SnO₂ and TiO₂ may be stacked from the substrate 1 side to the light-absorbing layer 3 side. It is preferred that the layer of the first electrode 2 in contact with the light-absorbing layer 3 is an oxide layer of any one of ITO, SnO₂ and TiO₂. In addition, a layer containing an oxide such as SiO₂ may be further provided between the substrate 1 and ITO. A film of the first electrode 2 may be formed by sputtering on the substrate 1. The film thickness of the first electrode 2 is, for example, 100 nm or more and 1000 ms or less. In the case of using the solar cell of the embodiment in a multi-junction solar cell, the solar cell of the embodiment is present in a top cell side, or a middle cell side, and thus, it is preferred that the first electrode 2 is a light-transmitting semiconductor film.

(Dot Region)

A dot region 4 according to the first embodiment refers to a region having a plurality of conductive metal parts 7 present on a surface of the first electrode 2 opposing the second electrode 5. This metal part 7 is present on an interface between the first electrode 2 and the light-absorbing layer 3. In addition, as in the third embodiment described below, the metal part may penetrate through the first electrode 2. The dot region 4 is a region in which the metal part 7 is present, and an aperture ratio ([an area where the metal part 7 is absent]/[(an area where the metal part 7 is present)+(an area where the metal part 7 is absent)]) is 50% or more. The metal part 7 is present in a non-aperture portion.

In the non-aperture portion, the metal part 7 is in contact with a surface of the light-absorbing layer 3 facing a direction of the first electrode 2, or formed to the inside of the light-absorbing layer 3. In addition, a surface on the opposite side to the surface of the metal part 7 in contact with the light-absorbing layer 3 is in contact with a surface of the first electrode 2 facing the light-absorbing layer 3, or in contact with the surface of the substrate. In addition, in at least a part of an opening portion, that is, the region in which the metal part 7 is absent, the light-absorbing layer 3 is present. The dot region 4 has high light transmission to the first electrode 2, and has an effect of suppressing oxidation of a compound semiconductor forming the light-absorbing layer 3. It also has a function of suppressing formation of an oxidation region in the interface of the compound semiconductor and the first electrode 2, and as a contact part becomes the metal part 7, the electric field is concentrated on the portion of the metal part 7, and the interface recombination can be suppressed to improve open voltage. When oxidation of the light-absorbing layer 3 is suppressed, open voltage is improved to improve conversion efficiency. High light transmission is a characteristic suitable for being used as a top cell of the multi-junction solar cell. In addition, the solar cell of the present embodiment is suitable for use as not only the multi-junction solar cell, but also the solar cell requiring transparency.

It is preferred that the aperture ratio of the dot region 4 is 50% or more and 99.95% or less. It is not preferred that the aperture ratio is less than 50%, since the light transmission is lowered. The aperture ratio is represented by two significant figures (rounding off) at less than 99%, and by three significant figures or four significant figures (rounding off) at 99% or more. In addition, when the aperture ratio is more than 99.95%, the effect of preventing oxidation of the light-absorbing layer 3 by presence of the dot region 4 is hardly shown, and it is difficult to contribute to improvement of conversion efficiency.

The aperture ratio can be examined as follows.

For example, in the case of the solar cell using the substrate 1 having a light transmitting property, an optical microscope is used in a direction in which the metal part 7 can be visually confirmed, and the vicinity of the center of the solar cell is observed at a magnification of 40 times, as shown in FIG. 2. Here, the observation is performed with an avoidance of a scribe line. The and portion of the solar cell is not used for observation. When the metal part 7 cannot be observed, the magnification is appropriately changed. Since the aperture ratio is measured using the image at the time of observation, an image in which the metal part 7 is partially taken out of the first electrode 2 by side etching at the time of manufacturing the solar cell, or an image in which a special shape seen only in a part of the solar cell is present, like resist being present in an observation portion is not used, among the images.

This observation is performed at 20 points, and binarization processing of light and darkness was performed on each image, thereby determining the area of the region in which the metal part 7 is present (non-aperture portion), and the area of the region in which the metal part 7 is absent (aperture portion).

<Binarisation Processing>

First, the thus-obtained image is put into image processing software, and the input image is subject to binarization processing. Here, in the binarised image, a threshold value is set so that a white color is the metal part 7 portion, and a black color is the first electrode 2. An area ratio of the white color and the black color of the binarized image is determined, and a portion where the black color is present in the whole image is expressed by a percentage, which is the aperture ratio.

In the case of using the substrate 1 having no light transmitting property, a part of the solar cell is cut out, and etching or direct polishing from the second electrode is performed, thereby cutting out to the light-absorbing layer 3. When cutting out, with careful attention to over-etching or over-polishing, a portion where the first electrode 2 can be visually completely confirmed is not observed. Imaging by secondary ion mass spectrometry (SIMS) is performed on the cut surface, and with the observation field of 20 μm×20 μm, the metal part 7 and the first electrode 2 are identified.

The thus-obtained image is subjected to binarization with the presence or absence of the metal part, and the areas of the aperture portion and the non-aperture portion are determined to calculate the aperture ratio. This process is performed at 20 points.

In the case of a multi-junction solar cell 200 shown in FIG. 9 as described below, and the like, a bottom cell 202 is peeled off from the multi-junction solar cell 200 so that a top cell 201 is not damaged, thereby forming only the top cell 201, and then the measurement of the aperture ratio as described above is performed.

The aperture ratio determined by the above method satisfying the aperture ratio means that the dot region 4 satisfies the aperture ratio. That is, 50%≤aperture ratio≤99.5% is preferred. 61≤aperture ratio≤99.5% is more preferred. 80%≤aperture ratio ≤99.5% is still more preferred. Further, it is more preferred that the aperture ratio is satisfied at all of 20 points. This state means that the dot region 4 satisfies the aperture ratio as a whole.

It is preferred that the metal part 7 is composed of a material which does not react with the light-absorbing layer 3, or a material which hardly reacts with the light-absorbing layer 3. Accordingly, it is preferred that the metal part 7 contains any one or more of the metal, alloy and a conductive oxide. When the light-absorbing layer 3 contains Se or S, it is preferred that the material forming the metal part 7 is a material resistant to corrosion by Se or S. When it is a metal, a noble metal element or Mo is preferred. Therefore, it is preferred that the metal contained in the metal or alloy of the metal part 7 is any one or more of Mo, Ru, Rh, Pd, Ag, Ir, Pt and the like. As the conductive oxide, RuO₂, PdO, Rh₂O₃, PtO₂, IrO₂ and the like are preferred, in terms of corrosion resistance to Se and S. In addition, a metal capable of ohmic connection with the light-absorbing layer 3 is preferred. A metal or compound (oxide) having a deep work function is preferred. A metal or compound (oxide) having a work function of 5.4 eV or more is preferred. From these facts, it is more preferred that the metal part 7 contains any one or more of Mo, Pt, Ir and Pd. The metal part 7 may be composed of one material or a combination of two or more materials. In addition, the metal part 7, or a compound including at least one selected from a group consisting of S, Se, Te, N and O which can be used instead of the void 8 as described below partially reacts when manufacturing the solar cell, so that the reaction product thereof may be present around the metal part 7.

The shape of the metal part 7 is not particularly limited. The specific example of the shape of the metal part 7 may include a circle, an ellipse, a polygon, and the like. The circle, ellipse and polygon thereof may be hollow (O shape, etc.) or have an aperture (C shape, a bracket shape, and the like), but are not particularly limited. It is preferred that the size of the metal part 7 is 2 nm or more and 20 μm or less. It is more preferred that the size of the metal part 7 is 6 nm or more and 10 μm or less. When the metal part 7 is unduly small, it is difficult to diffuse it on a surface of the first electrode 2. In addition, when the metal part 7 is unduly large, a variation in light transmission occurs, or light-absorbing layer 3 is easily oxidized, which is thus, not preferred. The height of the metal part 7 in the dot region 4 is not particularly limited. However, 2 nm or more and 50 μm or less is preferred, in terms of ease of manufacture. When the mobility of the light-absorbing layer 3 is not very high, it is preferred to use the metal part 7 having a hollow shape with a hole, since the space between metals is decreased, while the aperture ratio is increased. When the metal part 7 is formed on the first electrode 2 by applying and drying a solution containing metal particles, the metal particles are sometimes partially agglomerated. In addition, it is not necessary for each of the metal parts 7 to have an independent circular shape or elliptical shape, and a mesh-shaped metal net may be disposed on the first electrode 2.

It is preferred that the metal part 7 is dispersed to be present between the light-absorbing layer 3 and the first electrode 2. Therefore, it is preferred that the dot region 4 satisfies the aperture ratio as a whole. In addition, it is preferred that the size difference between the metal parts 7 is small.

It is not preferred that the metal parts 7 are unevenly distributed, since in the region in which there are a lot of the metal parts 7, light transmission is low, and in the region in which there are a few metal parts 7, the surface of the light-absorbing layer 3 facing the first electrode 2 is easily oxidized. Therefore, it is preferred that the interval difference between the metal parts 7 in the dot region is mall. It is preferred that the minimum value and the maximum value of the interval of the metal part 7 in the dot region is 0.8 times or more and 1.2 times or less of the average value of the interval of the metal part 7. It is more preferred that the minimum value and the maximum value of the interval of the metal part 7 in the dot region are 0.9 times or more and 1.1 times or less of the average value of the interval of the metal part 7.

It is preferred that the interval of the metal part 7 is 0.5 m or more and 24 μm or less. When the metal part 7 is uniformly dispersed as such, a deviation in light transmitting property is small, and the optical properties of the solar cell 100 is improved, and also, it is preferred that the metal part 7 has the same size at the same aperture ratio, since the more uniformly dispersed it is, the more improved the oxidation prevention function of the light-absorbing layer 3 is. This is considered to be because oxidation is likely to proceed in the region in which the metal part 7 is present in a small number or absent, and even with a small number of the metal parts 7, formation of an oxide film is inhibited, resulting in improvement of conversion efficiency.

It is preferred that the interval of the metal part 7 is in particular 0.8 nm or more and 200 nm or less. Within this range of the interval of the metal part 7, a void 8 as described below can be efficiently manufactured, and the efficiency of the solar cell can be improved.

The dot region 4 can be formed by a method of applying and drying a liquid containing metal particles which become the metal part 7, or a method of forming a metal film, an oxide film or a nitride film, and processing the film using a mask to have an optional metal part pattern, or a method of using a template having a metal part pattern shape to perform imprinting.

For example, after manufacturing the first electrode 2, a metal part pattern is manufactured with a resist mask. Thereafter, the material of the metal part 7 is sputtered. Then, the resist is peeled off to manufacture the metal part 7.

(Void)

The void 8 according to the present embodiment is present in at least a part between the metal parts 7 in the dot region 4. The void 8 is formed at the time of manufacturing the light-absorbing layer 3 as described below. In order to observe the shape of the void 8, for example, the dot region 4 is observed with a bright field image of a transmission electron microscope (TEM) of 50,000 times at an acceleration voltage of 200 kV, using JEM-ARM200F manufactured by JEOL Ltd., from the second electrode side.

The void 8 can be observed with the observation of a TEM bright field image, by determining the region in which the detection value of main constituent element is 50% or less as the void 8, when performing analysis using energy dispersive X-ray spectroscopy (EDX) of TEM.

Though the void 8 is present in at least a part between the metal parts 7, the void 8 does not necessarily have to be in contact with the metal part 7. For example, there are a case that the void 8 is in contact with the first electrode but a light-absorbing layer is present between the metal part 7 and the void 8, a case that the void 8 is in contact with neither the first electrode nor the metal part 7, a case that the void 8 is in contact with the metal part 7 but not in contact with the first electrode, a case that the void 8 is present between the metal parts 7 but not in contact with the first electrode, and the like. In addition, there is also a case that the void 8 is present by covering a part of the metal part 7.

Regardless of the shape of the void 8, it is preferred that the contact area between the first electrode and the void 8 is large, since the parallel resistance is maintained high.

The amount of the void 8 to be present in the entire solar cell affects the efficiency of the solar cell. The amount of the void 8 to be present is larger as the void fraction measured in the cross section of the solar cell is larger. In addition, as the amount of the void 8 to be present is larger, it is easier to increase the contact area between the void 8 and the first electrode 2.

The void fraction refers to a ratio of the void 8 present between the metal parts 7, relative to a distance between a certain metal part 7 and the closest metal part 7.

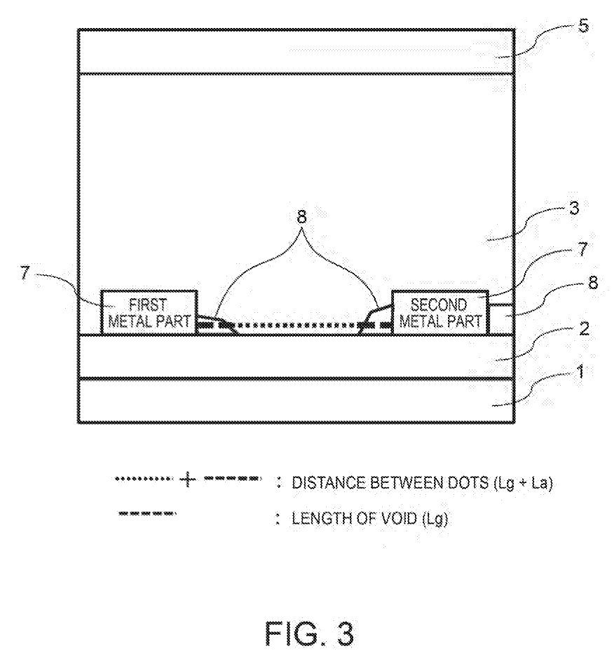

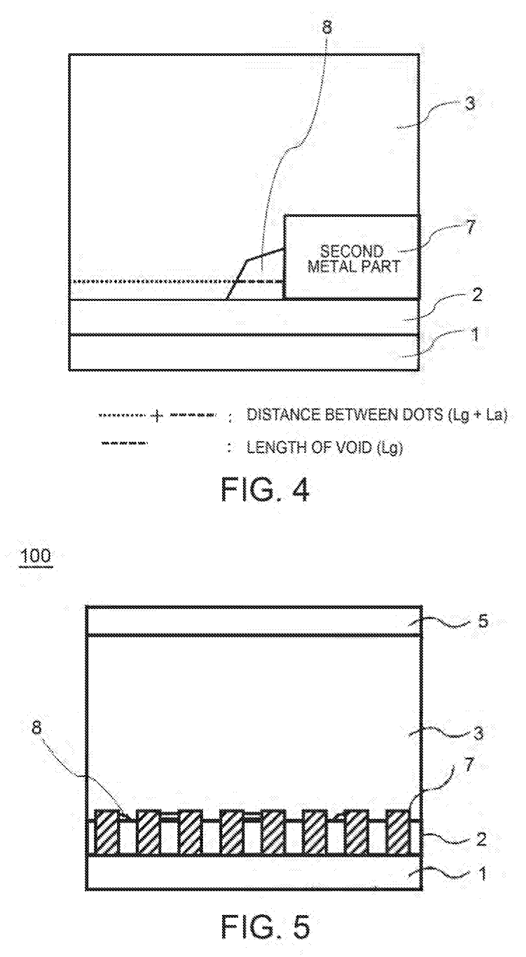

Here, the method of measuring void fraction is described. The void fraction is measured by taking TEM bright field images at 20 points, i.e., 20 cross sections of the solar cell, and using these TEM images. The measured images are shown in FIGS. 3 and 4.

First, in order to manufacture the cross section of the solar cell, the solar cell is cut with a straight line passing through any one metal part 7 and another metal part 7 closest to this metal part 7, thereby manufacturing a cross section. The closest metal part 7 is identified by observing the solar cell from the substrate side.

The cross section of the solar cell is observed by TEM. First, the thus-obtained cross section is formed into a sample suitable for TEM imaging, by using a focused ion beam (FIB). For observation of the manufactured sample, JEM-ARM 200F manufactured by JEOL Ltd., is used, with an accelerating voltage set to 200 kV, and there are two metal parts 7 and a void 8 in the field of view. For convenience, the two metal parts 7 in the imaging are referred to as a first metal part 7, and a second metal part 7.

For each of the TEM images taken as 20 cross sections, obtained as described above, the maximum distances between the first electrode 2 and the surfaces of the first metal part 7 and the second metal part 7 facing a direction of the second electrode 5 (maximum film thickness at each metal part 7) are measured. The distances herein are referred to as Rd1 and Rd2.

Next, the length ratio of the void 8 and a portion where the light-absorbing layer 3 is present in the imaging is determined. Here, the TEM image is appropriately enlarged to determine the length ratio of the void 8 and the light-absorbing layer 3.

This ratio is determined as follows. The first metal part 7 and the second metal part 7 are connected by a straight line parallel to the first electrode, in each TEM image, and the length of the portion on the straight line where the void 8 is present (the sum of each broken line in the case that the line is broken), and the length of the portion of the straight line where the light-absorbing layer 3 is present (the sum of each broken line in the case that the line is broken) are determined, which are set as Lg and La, respectively.

These Lg and La are determined at an interval of 10 nm to the height from directly above the first electrode to any smaller one of Rd1 and Rd2, i.e., min (Rd1, Rd2). The ratios of the void 8 in Lg, La and a distance between the metal parts 7 at a certain height, i.e., Rsp=Lg/(Lg+La), are determined, respectively.

Among Rsp−Lg/(Lg+La) at the height to sin (Rd1, Rd2) which is determined as described above, Max (Rap) is defined as void fraction.

The presence of the void 8 in contact with the first electrode 2 makes it possible to suppress the electrical conduction of the first electrode 2 and the light-absorbing layer 3 in the portion other than the necessary portion, thereby improving the characteristics of the solar cell.

In addition, the refractive indexes of the light-absorbing layer 3 and the first electrode 2 are often relatively high, and the reflection thereof at the interface is easily suppressed. Since light which is not sufficiently absorbed in the light-absorbing layer 3 is a loss of power generation, it is preferred that the reflection occurs in front of the first electrode 2. Since the presence of the void 8 introduces a region having a low refractive index, an effect of reflection inside the light-absorbing layer 3 can be obtained.

Therefore, in the solar cell of the present embodiment, even in the case that the void fraction obtained from the observation result of a TEM cross section of some of 20 cross sections is about 0%, when the average void fraction of 20 cross sections is about 18 or more, the characteristics of the solar cell can be improved. This is because the conversion efficiency of the light-absorbing layer 3 can be increased by scattering of light by the void 8, while the presence of the void 8 can reduce the contact between the light-absorbing layer 3 and the first electrode 2.

It is preferred that the void fraction is 10% or more, since the efficiency of the solar cell can be further improved by the action of the above-described void 8.

Instead of the void, a compound including at least one selected from a group consisting of S, Se, Te, N and O can be provided. In this case, the value corresponding to the void fraction can be also measured in the same manner as the method of measuring void fraction. This compound represents a compound having an insulation property, that is, a high-resistance compound.

(Light-Absorbing Layer)

The light-absorbing layer 3 of the present embodiment is a hetero-bonded layer or a homo-bonded layer including n-type and p-type compound semiconductor layers. It supplies electrons from the n-type and p-type compound semiconductors to the second electrode 5, by the light which is present between the first electrode 2 and the second electrode 5, and transmitted from above the second electrode 5.

As the n-type semiconductor layer, an n-type semiconductor having a controlled fermi level is preferred so that a photoelectric conversion element having a high open voltage can be obtained. As the n-type layer, for example, Zn_{1-y}MyO₁₋ₓSₓ, Zn_{1-y-z}Mg_{z}MyO, ZnO₁₋ₓSₓ, Zn_{1-z}Mg_{z}O (N is at least one element selected from a group consisting of B, Al, In and Ga), or CdS, or the like may be used. It is preferred that the thickness of the n-type layer is 2 nm or more and 800 nm or less. The n-type layer is formed by, for example, sputtering or CBD (chemical bath deposition). When the n-type layer is formed by CBD, for example, it can be formed on the light-absorbing layer 3, by a chemical reaction of a metal salt (e.g., CdSO₄), a sulfide (thiourea) and a complexing agent (ammonia) in an aqueous solution. When a chalcopyrite type compound of a Group IIIb element which does not contain In such as CuGaSe₂ layer, AgGaSe2 layer, CuGaAlSe₂ layer and CuGa(Se, S)₂ layer is used in the light-absorbing layer 3, CdS is preferred as the n-type layer.

The p-type compound semiconductor contains a compound including Groups I, III and VI elements. It is preferred that the Group I element includes at least Cu. It is preferred that the Group III element includes at least Ga. It is preferred that the Group VI element includes at least Se. A compound semiconductor layer having a chalcopyrite structure including a Group I (Group Ib) element, a Group III (Group IIIb) element and a Group VI (Group VIb) element, such as Cu(In,Ga)Se₂ or CuInTe₂, CuGaSe₂, Cu(In,Al)Se₂, Cu(Al,Ga) (S,Se)₂, Cu(In,Ga) (S,Se)₂ CuGa(S,Se)₂, Ag(In,Ga)Se₂ may be used as the light-absorbing layer 3. It is preferred that the Group Ib element is Cu or consists of Cu and Ag, the Group IIIb element consists of one or more elements among Ga, Al and In, and the Group VIb element consists of one or more elements among Se, S and Te. Among them, it is more preferred that the Group Ib element consists of Cu, the Group IIIb element consists of Ga, Al, Ga and In, or Ga and Al, and the Group VIb element consists of Se, S, or Se and S. When In in the Group IIIb element is contained at a small amount, it is preferred that the band gap of the light-absorbing layer 3 is easily adjusted to a preferred value, as the top cell of the multi-junction solar cell. The film thickness of the light-absorbing layer 3 is, for example, 800 nm or more and 3000 nm or less.

A combination of the elements makes it easy to adjust the size of the band gap to a desired value. The desired value of the band gap is, for example, 1.0 eV or more and 2.7 eV or less.

An example of a film forming method of the light-absorbing layer 3 may include a deposition process such as a three-step method, and the like, and the method is not limited as long as it can form a film having the void 8 on the first electrode 2 having the dot region 4. However, it is necessary to pay attention to the temperature condition. When the film formation is performed at high temperature in order to promote crystal growth, the light-absorbing layer 3 grows to the portion between metal parts 7 with the growth of the crystal, which makes it difficult to form the void 8. When the film formation temperature is lowered, the void 8 easily occurs on the portion between the metal parts 7. However, when the temperature is excessively lowered, the crystallinity of the light-absorbing layer 3 is deteriorated to deteriorate the characteristics of the solar cell. Accordingly, the light-absorbing layer 3 having the void 8 can be manufactured by lowering the temperature to the range in which the crystal growth is not suppressed. When the film formation temperature is described by taking molecular beam epitaxy (MBE) as an example, and the film formation is performed in the range of 500° C. to 550° C. at the maximum, the good light-absorbing layer 3 is likely to occur. However, this temperature varies with the measurement environment, and is only an indication.

Here, a deposition method by a three-step method using MBE is described as an example.

(First step) A substrate is heated to a temperature of 200° C. or more and 400° C. or less, and a Group IIIb element (e.g., Ga) and a Group VIb element (e.g., Se) are deposited.

(Second step) The substrate is heated to 300° C. or more and 600° C. or less, and a Group Ib element (e.g., Cu) and a Group VIb element (e.g., Se) are deposited. The initiation of an endothermic reaction is confirmed, and the deposition of the Group Ib element and the Group VIb element is stopped at the composition in which the Group Ib element (e.g., Cu) is excessive.

(Third step) After initiation of the endothermic reaction, it is preferred that the supply is continued further for about 5% or more of the supply time of the Group Ib element, since the quality of the crystal is increased. After completing the second step, the Group IIIb element and the Group VIb element are deposited again. By stopping the deposition at a composition in which the Group IIIb element is slightly excessive to the group Ib element, the leakage by the Group Ib-VIb compound present in the bulk (e.g., a Cu—Se compound) can be suppressed.

For the temperature of the second step, higher temperature is preferred, since the quality of the crystal is high. However, when the crystal is grown excessively, the void 8 between the metal parts 7 may be filled. In addition, when the temperature of the second step is low, the particle growth of the crystal is not promoted, and the deterioration of the characteristics of the solar cell is shown. Therefore, it is preferred to form a film at a substrate temperature of the second step in a range of 450° C. to 570° C. In this condition, the void 8 can be clearly confirmed. As the film formation temperature is high, the size of the void 8 tends to be small.

Even for the solar cell having an intermediate layer on the first electrode 2, and the dot region 4 on the intermediate layer, the film forming method of the light-absorbing layer 3 is identical, and the void 8 can be also present identically.

(Second Electrode)

The second electrode 5 according to the first embodiment is an electrode film which transmits light such as sunlight while having conductivity. The second electrode 5 is physically in contact with a surface opposite to the surface of the intermediate layer or the n-type layer facing the light-absorbing layer 3 side. There are the light-absorbing layer 3 and the n-type layer bonded to each other, between the second electrode 5 and the first electrode 2. The film formation of the second electrode 5 is performed, for example, by sputtering CVD (chemical vapor deposition) under an Ar atmosphere. As the second electrode 5, for example, ZnO:Al using a ZnO target containing 2 wt % of alumina (Al₂O₃), or ZnO:B containing B from diborane or triethylboron as a dopant may be used.

<Modification>

(Oxide Layer)

In the present embodiment, an oxide layer may be provided. The oxide layer is a thin film which is preferably provided between the n-type layer and the second electrode 5. The oxide layer is a thin film containing any one compound of Zn₁₋ₓMgₓO, ZnO_{1-y}S_{y} and Zn₁₋ₓMgₓO_{1-y}S_{y} (0≤x, y<1). The oxide layer may be in the form of not covering the entire surface of the n-type layer facing the second electrode 5 side.

For example, the oxide layer may cover 50% of the surface of the n-type layer on the second electrode 5 side. As another candidate, a wurtzite type AlN, GaN, BeO, or the like may be listed. When the volume resistivity of the oxide layer is 1 Ωcm or more, it is possible to suppress a leak current derived from a low resistant component which may be present in the light-absorbing layer 3. In the present embodiment, the oxide layer may be omitted. These oxide layers are oxide particle layers, and it is preferred to have a plurality of voids 8 in the oxide layer. The intermediate layer is not limited to the above compound or physical properties, and only a layer contributing to the improvement of the conversion efficiency of the solar cell. The intermediate layer may be a plurality of layers having different physical properties.

(Third Electrode)

In the present embodiment, a third electrode may be provided. The third electrode is an electrode of the solar cell 100, and a metal film formed on the opposite side to the light-absorbing layer 3 side on the second electrode 5. As the third electrode, a conductive metal film such as Ni or Al may be used. The film thickness of the third electrode is, for example, 200 nm or more and 2000 nm or less. In addition, when the resistance value of the second electrode 5 is low and the series resistance component is negligible, the third electrode may be omitted.

(Anti-Reflection Film)

In the present embodiment, an anti-reflection film may be provided. The anti-reflection film is a film for allowing light to be easily introduced to the light-absorbing layer 3, and formed on the opposite side to the light-absorbing layer side on the second electrode or the third electrode. As the anti-reflection film, it is preferred to use, for example, MgF₂, SiNₓ or SiO₂. In the present embodiment, the anti-reflection film may be omitted. It is necessary to adjust the film thickness depending on the refractive index of each layer. However, it is preferred to perform deposition at 70-130 nm (preferably 80-120 nm).

The solar cell according to the present embodiment is composed of the first electrode 2, the second electrode 5, the light-absorbing layer 3 provided between the first electrode 2 and the second electrode 5, and a plurality of metal parts 7 present on the surface of the first electrode 2 opposing the second electrode 5, and the void 8 is provided in at least a part between the plurality of metal parts 7.

By providing the solar cell according to the first embodiment, the parallel resistance of the characteristics of the solar cell can be maintained high, the shape factor can be maintained, and the difference in the refractive index between the light-absorbing layer 3 and the void 8 is large. Thus, the incident light is partially reflected to increase absorption inside the light-absorbing layer 3, thereby improving the conversion efficiency. In addition, oxidation of the light-absorbing layer 3 can be inhibited, thereby improving the conversion efficiency.

### Second Embodiment

The parts common to the first embodiment are emitted.

In the second embodiment, the metal part 7 in the dot region 4 is formed so that it passes through the first electrode 2 adjacent to a surface of the substrate 1, as shown in FIG. 5, and as a result, the metal part 7 is in contact with both of the substrate 1 and the light-absorbing layer 3. This metal part 7 is only in contact with the substrate 1, and, for example, the metal part 7 may be formed so that is passes through the first electrode 2 to the inside of the light-absorbing layer 3, as shown in FIG. 5. In addition, in the case of obtaining the action of the present embodiment, the metal part 7 is not formed to the surface in the light-absorbing layer side of the first electrode 2, and may be formed to the inside of the first electrode 2.

It can be examined whether the metal part 7 is in contact with the substrate 1 or not by observing the cross section of the solar cell, as described in the first embodiment.

Next, the method of manufacturing the metal part 7 in the present embodiment is described.

On the substrate 1, the film formation of a material of the metal part 7 is performed. Using a resist mask, the metal part 7 is processed into a predetermined pattern. Thereafter, the material to be the first electrode 2 is formed into a film by sputtering or the like. The resist mask is removed. Thereafter, the material to be the light-absorbing layer 3 is formed into a film by sputtering or the like. The film forming method of this light-absorbing layer 3 is as described above. The material to be the second electrode 5 is formed into a film by sputtering or the like.

The manufacturing method is not limited only to the above. For example, a material to be the first electrode 2 is formed into a film on the substrate 1 by sputtering, and thereafter, using a resist mask, the first electrode 2 is processed into a predetermined pattern, and the material to be the metal part 7 is sputtered. Finally, the resist mask is removed. It is possible to perform this manufacturing method identically.

By providing the solar cell according to the present embodiment, the parallel resistance of the characteristics of the solar cell can be maintained high, the shape factor can be maintained, and the difference in the refractive index between the light-absorbing layer 3 and the void 8 is large. Thus, the incident light is partially reflected to increase absorption inside the light-absorbing layer 3, thereby improving the conversion efficiency. In addition, oxidation of the light-absorbing layer 3 can be inhibited, thereby improving the conversion efficiency. In addition, since the metal part 7 and the substrate 1 are in contact with each other, electrons and holes are easily moved from the substrate 1 into the light-absorbing layer 3 via the metal part 7, thereby improving the current properties.

### Third Embodiment

The parts common to the first embodiment are omitted.

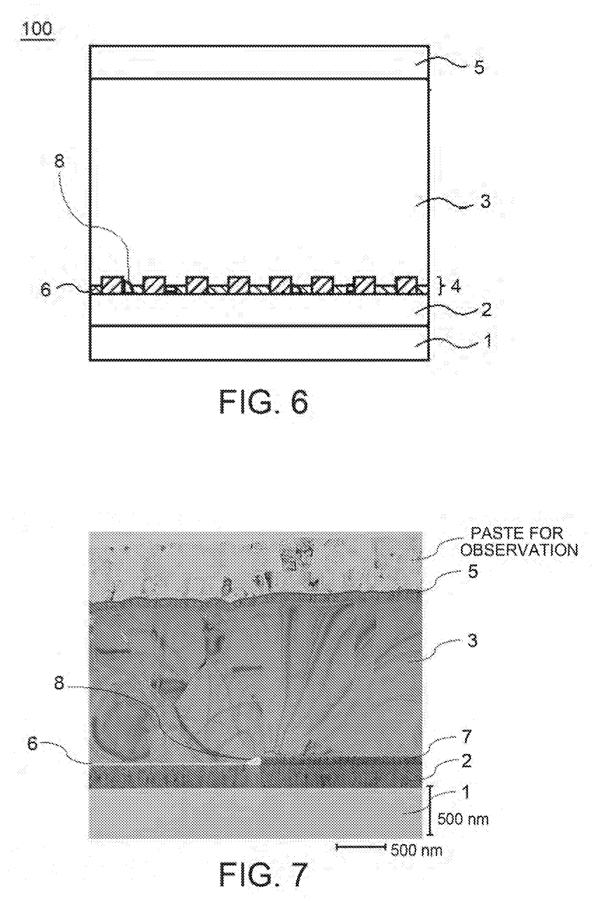

As shown in FIGS. 6 and 7, in the solar cell 100 according to the third embodiment, a first insulating film 6 is provided between the metal parts 7 in the dot region 4. The void 8 is present at least a part between the metal part 7 and the first insulating film 6, and/or at least a part between the light-absorbing layer 3 and the first insulating film 6. A paste for observation on the second electrode 5 in FIG. 7 is produced by the processing performed when observing it using TEM, which is not the configuration of the present embodiment.

When the metal part 7 in the dot region 4 has a hollow shape with a hole (e.g., O shape), it does not matter whether the first insulating film 6 or the void 8 is present in the hollow portion. When the first insulating film 6 or the void 8 is not present in the hollow portion of the metal part 7, the light-absorbing layer 3 enters the hollow region, and directly touches the first electrode 2, thereby reducing the parallel resistance, and thus, it is preferred that the first insulating film 6 or the void 8 is present. Except for the first insulating film 6, the solar cell is common to the solar cell 100 of the first embodiment. The description common to the first embodiment is omitted.

(First Insulating Film)

The first insulating film 6 is present on all over or a part of the surface between the light-absorbing layer 3 (among the metal parts 7) and the first electrode 2. The first insulating film 6 is a film having light transmission which prevents oxidation of the light-absorbing layer 3. The surface of the first electrode 2 facing the light-absorbing layer side is physically in contact with the surface of first insulating film 6 facing the first electrode 2 side. The surface of the light-absorbing layer 3 facing the first electrode side is physically in contact with the surface of the first insulating film 6 facing the light-absorbing layer side. The side surface of the first insulating film 6, that is, the surface facing the dot region side is physically in contact with the metal part 7 or the light-absorbing layer 3. The oxidation of the light-absorbing layer 3 can be partially prevented by the dot region 4, and in terms of the oxidation prevention, the aperture ratio of the dot region 4 should be low, but which leads to reduction of the transmittance of light and thus, is not preferred. In addition, the first insulating film 6 is provided on the entire surface between the light-absorbing layer 3 and the first electrode 2, and in the solar cell which is not provided with the dot region 4, the contact between the first electrode 2 and the light-absorbing layer 3 is not good, thereby not improving the conversion efficiency.

When the first insulating film 6 is simply introduced, the series resistance component (Rs) of the solar cell is higher to reduce efficiency. When the first insulating film 6 is introduced on the first electrode 2, the contact portion between the first electrode 2 and the light-absorbing layer 3 is physically reduced (the insulation region corresponding to a passivation film) to further suppress interface recombination, thereby maintaining high open voltage.

When the first insulating film 6 is present between the light-absorbing layer 3 and the first electrode 2, the electric conduction between the first electrode 2 and the light-absorbing layer 3 can be suppressed, and a fill factor (FF) is improved to improve the conversion efficiency. An example of the first insulating film 6 may include any one of an oxide film or a nitride film. As the oxide film, specifically, any one or more films of AlO, SiOₓ, MgO and (Al, Si, Mg)Ox are preferred. In addition, as a nitride film, any one or more films of SiN, AlN, GaN and (Si, Al, Ga)Nₓ are preferred. The thickness of the first insulating film 6 may be larger than the height of the metal part 7 in the dot region 4. However, preferably, it is a height of the metal part 7 or less, and 1 nm or more and 80 nm or less. The thickness of the first insulating film 6 is the height of the metal part 7 or less, and more preferably 5 nm or more and 50 nm or less. The first insulating film 6 has the effect even though it does not cover the entire surface between the light-absorbing layer 3 (among the metal parts 7) and the first electrode 2. In terms of the oxidation prevention and FF improvement, and in terms of the film formation process, it is preferred that the first insulating film 6 is present on all over the entire surface between the light-absorbing layer 3 (among the metal parts 7) and the first electrode 2.

The method of forming the first insulating film 6 can adopt a semiconductor manufacturing process. For example, a metal film for the dot region 4 is formed on the first electrode 2, and processed into a metal part 7 pattern using a resist mask, thereby forming the dot region 4. Subsequently, the material to be the first insulating film 6 is formed into a film on the resist mask in the dot region 4 and the exposed surface of the first electrode 2 by sputtering and the like. The first insulating film 6 on the dot region 4 is removed together with the resist mask, and the film formation of the light-absorbing layer 3 can be performed in the same manner as in the first embodiment.

Here, when a part of the surface of the metal part 7 in contact with the light-absorbing layer 3 is covered with the first insulating film 6, the electric conductivity of the metal part 7 and the light-absorbing layer 3 is deteriorated. In this case, since the contact resistance is increased with the same transmittance being maintained, the open voltage (Voc) is decreased, and the efficiency is also reduced. Thus, it is preferred that the void 8 is present.

The first insulating film 6 may have a mesh shape. The first insulating film 6 may have more voids 8 by taking the mesh shape. In this case, a region having a low refractive index is introduced while maintaining the insulation property. Thus, a reflecting effect inside the light-absorbing layer can be obtained.

The void 8 in the solar cell according to the third embodiment is not necessarily in contact with the metal part 7, like the void 8 described in the first embodiment. There are cases such as a case that the void 8 is in contact with the first electrode 2 and the first insulating film 6 but the light-absorbing layer 3 is present between the metal part 7 and the void 8, a case that the void 8 is in contact with the first electrode 2 and the metal part 7 but the light-absorbing layer 3 is present between the first insulating film 6 and the void 8, a case that the void 8 is in contact with the first electrode 2 but positioned between the metal part 7 and the first insulating film 6 in contact with neither of them, a case that the void 8 is not in contact with any one of the first electrode 2, the metal part 7 and the first insulating film 6, and a case that the void 8 is in contact with the metal part 7 and the first insulating film 6 but not in contact with the first electrode 2. In addition, there is also a case that the void 8 is present by covering a part of the metal part 7 or the first insulating film 6.

The method of measuring void fraction is as described in the first embodiment.

By the presence of the void 8, the insulation property of the first electrode 2 and the light-absorbing layer 3 is increased, which leads to improvement of the characteristics of the solar cell, as described in the first embodiment. Like the light-absorbing layer 3 or the first electrode 2, the refractive index of the first insulating film 6 is often high, and the reflection thereof at the interface is easily suppressed. Since light which is not sufficiently absorbed in the light-absorbing layer 3 is a loss of power generation, it is preferred that the reflection occurs in front of the first electrode 2. Since the presence of the void 8 introduces a region having a low refractive index, an effect of reflection inside the light-absorbing layer 3 can be obtained.

In a case that the first insulating film 6 fills the spaces among the metal parts 7 so that the void 8 is absent, the first insulating film 6 and the metal part 7 react with each other depending on the type of the first insulating film 6 and heating processing, so that an undesired conductive portion is included in a part of the first insulating film 6, which generates a possibility to deteriorate the contact. By presence of the void 8 between the metal part 7 and the first insulating film 6, a conductive portion other than the metal part 7 is not provided, while intending the insulation maintenance among the metal parts 7 and the efficiency improvement by reflection. Thus, it is more preferred that the void 8 is present between the metal part 7 and the first insulating film 6.

By providing the solar cell according to the present embodiment, the parallel resistance of the characteristics of the solar cell can be maintained high, the shape factor can be maintained, and the difference in the refractive index between the light-absorbing layer 3 and the void 8 is large. Thus, the incident light is partially reflected to increase absorption inside the light-absorbing layer 3, thereby improving the conversion efficiency. In addition, oxidation of the light-absorbing layer 3 can be inhibited, thereby improving the conversion efficiency. Furthermore, the first electrode 2 and the light-absorbing layer 3 are not in contact with each other to occur no direct conduction therebetween, thereby improving the contact state between the metal part 7 and the light-absorbing layer 3.

### Fourth Embodiment

The parts common to the first to third embodiments are omitted.

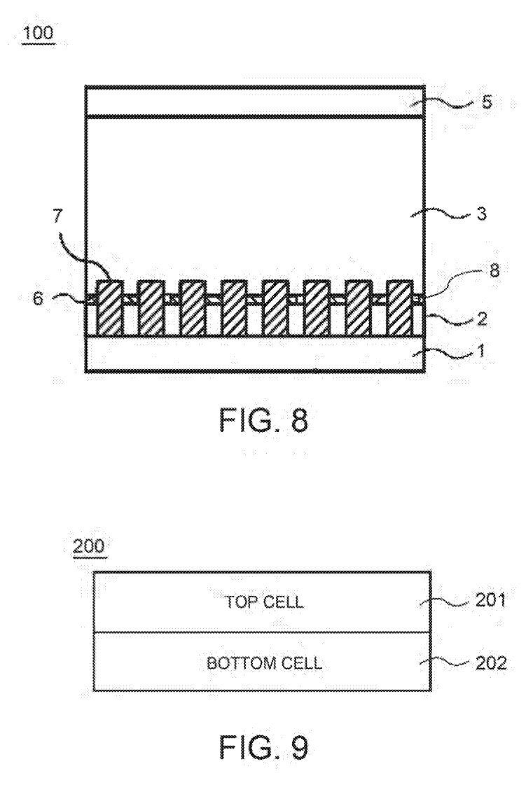

The solar cell according to the present embodiment has the first insulating film 6 between the metal parts 7 in the dot region 4, as shown in FIG. 8. The void 8 is present between the metal part 7 in the dot region 4 and the first insulating film 6. The metal part 7 is formed so that it passes from a surface of the substrate 1 through the first electrode 2 to a surface of the light-absorbing layer 3. As a result, the metal part 7 is in contact with both of the substrate 1 and the light-absorbing layer 3. This metal part 7 is only in contact with the substrate 1, and may be formed from the surface of the substrate 1 to the inside of the light-absorbing layer 3.

In addition, in a case that the action of any embodiment to be introduced can be obtained, the metal part 7 may not formed to the surface of the first electrode 2 at the light-absorbing layer side, and may be formed onto the inside of the first electrode 2.

By providing the solar cell according to the present embodiment, the parallel resistance of the characteristics of the solar cell can be maintained high, the shape factor can be maintained, and the difference in the refractive index between the light-absorbing layer 3 and the void 8 is large. Thus, the incident light is partially reflected to increase absorption inside the light-absorbing layer, thereby improving the conversion efficiency. In addition, oxidation of the light-absorbing layer 3 can be inhibited, thereby improving the conversion efficiency. In addition, since the metal part 7 and the substrate 1 are in contact with each other, electrons and holes are easily moved from the substrate 1 into the light-absorbing layer 3 via the metal part 7, thereby improving the current properties. Furthermore, the first electrode 2 and the light-absorbing layer 3 are not in contact with each other to occur no direct conduction therebetween, thereby improving the contact state between the metal part 7 and the light-absorbing layer 3.

### Fifth Embodiment

The fifth embodiment is a multi-junction solar cell using any one of the solar cells of the first to fourth embodiments, or a combination thereof. FIG. 9 represents a schematic cross-sectional view of the multi-junction solar cell of the present embodiment. The multi-junction solar cell of FIG. 9 has a solar cell of the top cell 201 and a solar cell of the bottom cell 202. The solar cells 100 of the first to fourth embodiments are used as the top cell 201 of the multi-junction solar cell 200. The light transmitted through the substrate 1 of the solar cell of the top cell 201 is then incident onto the solar cell of the bottom cell 202. As a battery of the bottom cell 202, for example, the solar cell having the light-absorbing layer 3 of Si, or the solar cell 100 (having the light-absorbing layer 3 which is a narrower gap than the solar cell of the top cell 201) of the first and second embodiments, can be used. In the case of using the solar cell 100 of the first embodiment as the top cell, it is preferred that the Group I element is Cu, the Group III element is Ga and In, and the Group VI element is Se and S, in terms of the absorption wavelength and the conversion efficiency. Since the light-absorbing layer 3 of the solar cell of the first embodiment is a wide gap, the light-absorbing layer 3 is preferably used as the top cell. In the case that the solar cell 100 of the first embodiment is used as the bottom cell, it is preferred that the Group I element is Cu, the Group III element is In and Ga, and the Group VI element is Se, in terms of the absorption wavelength and the conversion efficiency.

### Sixth Embodiment

The solar cells of the first to fifth embodiments can be used as a power generating element in a solar cell module of the present embodiment. The power generated by the solar cell of the present embodiment is consumed by a load electrically connected to the solar cell, or stored into a storage battery electrically connected to the solar cell.

An example of the solar cell module of the present embodiment may include a member in which the solar cell is connected by in plural, in series, in parallel, or in series and parallel, or a structure in which a single cell is fixed to a supporting member such as glass. In the solar cell module, a light collector may be provided and convert the light received in an area larger than an area of the solar cells into electric power. Among the solar cells, a solar cell connected in series, in parallel, or in series and parallel is included.

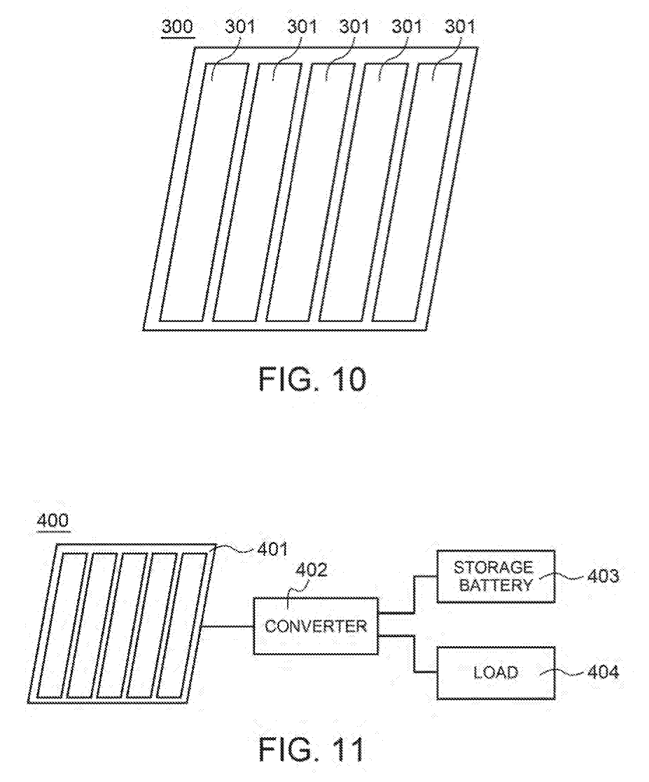

FIG. 10 represents a configuration conceptual diagram of the solar cell module 300 in which a plurality of the solar cells 301 is arranged by 5 cells in a horizontal direction. Though a connection wiring is omitted in the solar cell module 300 of FIG. 10, it is preferred that the plurality of the solar cells 301 is connected in series, in parallel, or in series and parallel, as described above. As the solar cells 301, it is preferred that those from the solar cell 100 of the first embodiment to the multi-junction solar cell 200 of the fifth embodiment are used. In addition, the solar cell module 300 of the present embodiment may adopt a module structure in which a module using those from the solar cell 100 of the first embodiment to the multi-junction solar cell 200 of the fifth embodiment and a module using other solar cells overlap each other. Besides, it is preferred to adopt a structure for raising the conversion efficiency. In the solar cell module 300 of the present embodiment, it is preferred that the solar cell 301 (having a photoelectric conversion layer of a wide band gap) is provided on a light receiving surface side.

### Seventh Embodiment

The solar cell module 300 of the sixth embodiment can be used as a power generator generating electricity, in a solar power generation system 400 of the present embodiment. The solar power generation system 400 of the present embodiment generates an electricity using the solar cell module, and specifically, has the solar cell module generating the electricity, a means for converting the generated electricity to an electric power, a storage means for storing the generated electricity, or a load consuming the generated electricity. FIG. 11 represents a configuration conceptual diagram of the solar power generation system 400 of the present embodiment. The solar power generation system of FIG. 11 includes the solar cell module 401 (300), a converter 402, a storage battery 403, and a load 404. Either of the storage battery 403 and the load 404 can be omitted. The load 404 may be configured to utilize an electric energy stored in the storage battery 403. The converter 402 is an equipment including a circuit or an element performing power conversion such as transformation and DC-AC conversion, for example, a DC-DC converter, a DC-AC converter and an AC-AC converter. The converter 402 only adopts a preferred configuration depending on the configuration of power generation voltage, the storage battery 403 or the load 404.

The light-received solar cell 301 included in the solar cell module 401(300) generates an electricity, and the electric energy is converted by the converter 402 to be stored into the storage battery 403, or consumed by the load 404. It is preferred that the solar cell module 401 is provided with a sunlight tracking drive device for constantly directing the solar cell module 401 to the sun, a light collector for collecting the sunlight, or a device for improving the power generation efficiency, and the like are added thereto.

It is preferred that the solar power generation system 400 is used in real estate such as residential facilities, commercial facilities or factories, or movable assets such as vehicles, aircrafts or electronic equipment. By using the photoelectric conversion element having excellent conversion efficiency of the present embodiment in the solar cell module 401, an increase of the power generation is expected.

Hereinafter, the present embodiments will be described in detail, based on the Examples. However, the present embodiments are not limited to the following Examples.

### EXAMPLES

### Example 1

A top cell is manufactured, and the conversion efficiency and the void fraction of the solar cell are measured.

First, a method of manufacturing the top cell is described. Soda-lime glass is used as a substrate. Films of ITO (150 nm) and SnO₂ (100 nm) are formed by sputtering as a first electrode (back first electrode). A Pd dispersion solution (stock solution 4 wt %, an average diameter 10 nm) is coated by a spray method, and overheated at 300° C. for 30 minutes in an oxygen stream to fly organic matter. After UV cleaning, by the method described in the first embodiment, the substrate is heated to 370° C., and Ga and Se(S) are deposited thereon. While the substrate temperature is heated to 520° C., Cu and Se(S) are deposited. When an endothermic reaction is shown, deposition is continued up to 10% of the Cu and Se(S) deposition time, and finally Ga and Se(S) are deposited. When a desired Cu/Ga composition is reached, Ga deposition is stopped, and annealing for 5 minutes is performed as it is, and thereafter, the substrate temperature is lowered. When the substrate temperature is lowered to 380° C., deposition of Se(S) is stopped.

A CdS layer is manufactured as an n-type layer by chemical bath deposition (CBD). Cadmium sulfate is dissolved in an aqueous ammonia, thiourea is added thereto, and the product is taken out after 300 seconds and then washed with water. An organic Zn compound is coated on the substrate by photolithography. Beating at 120° C. for 5 minutes is performed to manufacture a ZnO protective layer of 30 nm.

ZnO:Al is manufactured by sputtering as the second electrode (upper first electrode). It is preferred that the substrate temperature is from room temperature to 150° C. It is preferred that the manufacture is performed relatively at low temperature, since open voltage easily increases.

MgF₂ is deposited on the second electrode with a thickness of about 100 nm as an anti-reflection film.

The method of measuring conversion efficiency is as follows.

A solar simulator simulating a light source of AM 1.5G is used, and a Si cell as a reference under the light source is used to adjust a light quantity to be 1 sun. The temperature is 25° C. When a horizontal axis is voltage, and a vertical axis is current density, the point intersecting the horizontal axis is Voc, and voltage sweep is performed by a voltmeter from a value covering Voc (for example, 1.4 V) to the range capable of measuring Jsc (minus range, for example, −0.4 V), and the current value at this time is measured. The current value divided by the area of the solar cell is current density (mA/cm²), and a value of current density at the applied voltage of 0 V is Jac (short-circuit current density).

Efficiency (η) is calculated as follows.

η=Voc×Jsc×FF/P×100

P is incident power density by calibrating the simulated sunlight of AM 1.5 with the reference solar cell.

FF is calculated as follows.

FF=Vmpp×Jmpp/(Voc×Jac).

Vmpp and Jmpp are values of V and J at the point where the product of V×J is maximum.

Herein, in Table 1, the solar cell efficiency (FF) of the Examples was calculated, based on the Comparative Examples as described below. The efficiency of the Comparative Example is η, 1.02 η or more and less than 1.05 η is indicated as ⊚, and 1.05 η or more is indicated as ⊚⁺.

The method of measuring void fraction uses the method described in the first embodiment.

The results are summarized in Table 1. The results of Example 2 and Comparative Example 1 are also summarized in Table 1.

### Example 2

The same manufacturing process as Example 1 was performed, except that the substrate temperature is changed to 560° C. at the time of depositing Cu and Se.

### Comparative Example 1

The same manufacturing process as Example 1 was performed, except that the substrate temperature is changed to 600° C. at the time of depositing Cu and Se.

### Example 3

The method of manufacturing the top cell is described. High-transmittance glass or soda-lime glass is used as the substrate. Films of ITO (150 nm) and SnO₂ (100 nm) are formed by sputtering as a first electrode. A hole was made on the first electrode by lithography, and a metal part (introduction body diameter: 3 μm, thickness: 250 nm) was introduced. Here, the aperture ratio is 86%. In this Example, no is used as the metal part. Thereafter, the product is heated to 370° C., and Ga and Se(S) are deposited thereon. Cu and Se(S) are deposited while the substrate temperature is heated to 520° C. When an endothermic reaction is shown, deposition is continued up to 10% of the Cu and Se(S) deposition time, and finally, Ga and Se(S) are deposited. When a desired Cu/Ga composition is reached, Ga deposition is stopped, and annealing for 5 minutes is performed as it is, and thereafter, the substrate temperature is lowered. When the substrate temperature is lowered to 380° C., deposition of Se(S) is stopped. Note that, after a hole is made on the first electrode, the metal part may be introduced to the hole using an imprint. The methods of manufacturing the n-type layer, the second electrode and the third electrode are identical to those of Example 1.

The results are summarized in Table 2. The results of Example 4 and Comparative Example 2 are also summarised in Table 2.

### Example 4

The same manufacturing process as Example 3 was performed, except that the substrate temperature is changed to 560° C. at the time of depositing Cu and Se.

### Comparative Example 2

The same manufacturing process as Example 4 was performed, except that the substrate temperature is changed to 600° C. at the time of depositing Cu and Se.

### Example 5

The same manufacturing process as Example 1 was performed, except that SiNx was sputtered directly on the first electrode to manufacture an insulating film.

The results are summarized in Table 3. The results of Example 6 and Comparative Example 3 are also summarized in Table 3.

### Example 6

The same manufacturing process as Example 5 was performed, except that the substrate temperature is changed to 560° C. at the time of depositing Cu and Se.

### Comparative Example 3

The same manufacturing process as Example 5 was performed, except that the substrate temperature is changed to 600° C. at the time of depositing Cu and Se.

### Example 7

The same manufacturing process as Example 3 was performed, except that SiNx was sputtered directly on the first electrode to manufacture an insulating film.

The results are summarized in Table 4. The results of Example 8 and Comparative Example 4 are also summarized in Table 4.

### Example 8

The same manufacturing process as Example 7 was performed, except that the substrate temperature is changed to 560° C. at the time of depositing Cu and Se.

### Comparative Example 4

The same manufacturing process as Example 7 was performed, except that the substrate temperature is changed to 600° C. at the time of depositing Cu and Se.

TABLE 1

| | Porosity (%) | Efficiency |
|---|---|---|
| Example 1 | 12 | ⊚* |
| Example 2 | 8 | ⊚ |
| Comparative | 0 | ◯ |
| Example 1 | | |

TABLE 2

| | Porosity (%) | Efficiency |
|---|---|---|
| Example 3 | 10 | ⊚* |
| Example 4 | 7 | ⊚ |
| Comparative | 0 | ◯ |
| Example 2 | | |

TABLE 3

| | Porosity (%) | Efficiency |
|---|---|---|
| Example 5 | 12 | ⊚* |
| Example 6 | 9 | ⊚ |
| Comparative | 0 | ◯ |
| Example 3 | | |

TABLE 4

| | Porosity (%) | Efficiency |
|---|---|---|
| Example 7 | 10 | ⊚* |
| Example 8 | 8 | ⊚ |
| Comparative | 0 | ◯ |
| Example 4 | | |

From Tables 1 to 4, it is found that by the presence of the void, the efficiency of the solar cell was improved in any of the Examples. This is because, by the presence of the void having a low refractive index, the light can be reflected, and the light absorbable into the light-absorbing layer can be increased.

In addition, it is found that the higher the void fraction is, the more improved efficiency the solar cell has.

In addition, as the void fraction is higher, the light-absorbing layer and the first electrode are difficult to come into contact with each other, and thus, an insulating property can be improved.

It is found that the solar cell having a void has higher conversion efficiency than the solar cell having no void, in any embodiment described.

While certain embodiments have been described, these embodiments have been presented by way of examples only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solar cell comprising:
a first electrode;
a second electrode;
a light-absorbing layer interposed between the first electrode and the second electrode; and
a plurality of metal parts on a surface of the first electrode opposing the second electrode,
wherein a void is provided in at least a part between the metal parts.

2. The solar cell according to claim 1, wherein,
in each of a plurality of cross sections of the solar cell,
between a metal part and another metal part closest to the metal part among the metal parts,
when virtual straight lines at an interval of 10 nm are set from the surface of the first electrode in a direction toward the second electrode,
a ratio of a length of the void to a length between the metal part and the another metal part along each of the virtual straight lines is calculated,
a maximum value of the ratio among the virtual straight lines is set to a void fraction,
an average of the void fraction among the cross sections is 1% or more.

3. The solar cell according to claim 1, wherein,
in each of a plurality of cross sections of the solar cell,
between a metal part and another metal part closest to the metal part among the metal parts,
when virtual straight lines at an interval of 10 nm are set from the surface of the first electrode in a direction toward the second electrode,
a ratio of a length of the void to a length between the metal part and the another metal part along each of the virtual straight lines is calculated,
a maximum value of the ratio among the virtual straight lines is set to a void fraction,
an average of the void fraction among the cross sections is 10% or more.

4. The solar cell according to claim 1, wherein
at least a part of the void is in contact with the first electrode.

5. The solar cell according to claim 1, wherein
a distance between the metal parts is 0.8 nm or more, and 200 nm or less.

6. The solar cell according to claim 1, wherein
the metal part contains any one or more of metals, alloys, conductive oxides and conductive nitrides.

7. The solar cell according to claim 1, wherein
the metal part is formed of at least one element selected from a group consisting of Mo, Ta, Nb, W, Ru, Rh, Pd, Ag, Ir and Pt.

8. The solar cell according to claim 1, wherein
the metal part is formed so that the metal part passes from an opposite surface of the surface of the first electrode through the first electrode to the surface of the first electrode facing the light-absorbing layer.

9. The solar cell according to claim 1, wherein
the metal part is formed so that the metal part passes from an opposite surface of the surface of the first electrode through the first electrode to an inside of the light-absorbing layer.

10. The solar cell according to claim 1, wherein
an insulating film is provided between the metal parts on the surface of the first electrode opposing the second electrode, and
the void is provided in at least a part between the metal part and the insulating film.

11. The solar cell according to claim 10, wherein
the insulating film is formed of at least one selected from a group consisting of AlOₓ, AlNₓ, MgO, SiOₓ and SiNₓ.

12. A multi-junction solar cell using the solar cell according to claim 1.

13. A solar cell module using the solar cell according to claim 1.

14. A solar cell module using the multi-junction solar cell according to claim 12.

15. A solar power generation system using the solar cell module according to claim 13.

16. A solar cell comprising:
a first electrode;
a second electrode;
a light-absorbing layer interposed between the first electrode and the second electrode;
a plurality of metal parts on a surface of the first electrode opposing the second electrode; and
a compound including at least one selected from a group comprising of S, Se, Te, N and O in at least a part between the metal parts.

17. The solar cell according to claim 16, wherein
a distance between the metal parts is 0.8 nm or more, and 200 nm or less.

18. The solar cell according to claim 16, wherein
the metal part contains any one or more of metals, alloys, conductive oxides and conductive nitrides.

19. The solar cell according to claim 16, wherein
the metal part is formed of at least one element selected from Mo, Ta, Nb, W, Ru, Rh, Pd, Ag, Ir and Pt.

20. The solar cell according to claim 16, wherein
the metal part is formed so that the metal part passes from an opposite surface of the surface of the first electrode through the first electrode to at least the surface of the first electrode facing the light-absorbing layer.
